(19) United States
(12) Patent Application Publication
(10) Pub. No.: US 2026/0139382 A1
(43) Pub. Date: May 21, 2026

(54) SOLAR CELL AND FABRICATION METHOD THEREFOR, COATING DEVICE AND SOLAR CELL PRODUCTION SYSTEM

(71) Applicant: TONGWEI SOLAR (CHENGDU) CO., LTD., Chengdu (CN)

(72) Inventors: Chen WANG, Chengdu (CN); Feng GU, Chengdu (CN); Qian LONG, Chengdu (CN)

(73) Assignee: TONGWEI SOLAR (CHENGDU) CO., LTD., Chengdu (CN)

(21) Appl. No.: 19/452,796

(22) Filed: Jan. 19, 2026

Related U.S. Application Data
(63) Continuation of application No. PCT/CN2024/095533, filed on May 27, 2024.

(30) Foreign Application Priority Data
Jul. 18, 2023 (CN) 202310884652.5

(51) Int. Cl. C23C 28/04; H01J 37/32; H01J 37/34; H10F 77/20

(52) U.S. Cl. CPC C23C 28/04; H01J 37/32899; H01J 37/3405; H10F 77/247; H01J 2237/332

(57) ABSTRACT

A coating device includes a first physical vapor deposition chamber, a chemical vapor deposition chamber, and a second physical vapor deposition chamber. The first physical vapor deposition chamber is used to prepare the aforementioned first transparent conductive layer. The chemical vapor deposition chamber is in communication with the first physical vapor deposition chamber. The chemical vapor deposition chamber is used to prepare the aforementioned first interlayer film. The second physical vapor deposition chamber is in communication with the chemical vapor deposition chamber. The second physical vapor deposition chamber is used to prepare the aforementioned second transparent conductive layer.

### CROSS-REFERENCE TO RELATED APPLICATIONS

This application is a continuation of International Application No. PCT/CN2024/095533 filed on May 27, 2024, which claims priority to Chinese Patent Application No. 202310884652.5, filed on Jul. 18, 2023. All of the aforementioned applications are incorporated herein by reference in their entireties.

### TECHNICAL FIELD

The present application relates to the field of solar cell technologies, and in particular, to a solar cell and a fabrication method thereof, a coating device, and a solar cell production system.

### BACKGROUND

During preparation of a solar cell, it is usually necessary to prepare a transparent conductive (TCO) film on a substrate to be coated. Currently, indium tin oxide (ITO) is commonly used as material for the transparent conductive film. Among them, with increasing production capacity of solar cells, the demand for indium is also growing. However, current global indium production capacity and reserves are insufficient to support large-scale preparation of the solar cells. Furthermore, the relatively high cost of indium leads to increased costs of the solar cells, thereby severely limiting the application and widespread adoption of the solar cells.

### SUMMARY

A first aspect of the present application provides a solar cell. The solar cell includes a solar cell precursor and a first transparent conductive film. The first transparent conductive film is located on the solar cell precursor. The first transparent conductive film includes a first transparent conductive layer, a first interlayer film, and a second transparent conductive layer which are stacked in sequence on the solar cell precursor. And material of the first transparent conductive layer includes indium tin oxide, material of the first interlayer film is different from the material of the first transparent conductive layer, and material of the second transparent conductive layer includes indium tin oxide.

In a specific embodiment of the first aspect of the present application, the first interlayer film has a structure including at least two layers.

In a specific embodiment of the first aspect of the present application, the first interlayer film includes a first interlayer and a second interlayer, the first interlayer is located on the first transparent conductive layer, the second interlayer is located on the first interlayer, materials of the first interlayer and the second interlayer are selected from one of aluminum-doped zinc oxide and fluorine-doped tin oxide, and the material of the first interlayer is different from the material of the second interlayer. That is, the material of the first interlayer is selected from one of aluminum-doped zinc oxide and fluorine-doped tin oxide, and the material of the second interlayer is selected from another one of aluminum-doped zinc oxide and fluorine-doped tin oxide.

In a specific embodiment of the first aspect of the present application, the solar cell also includes a second transparent conductive film. The second transparent conductive film and the first transparent conductive film are respectively located on opposite surfaces of the solar cell precursor. The second transparent conductive film includes a third transparent conductive layer, a second interlayer film, and a fourth transparent conductive layer which are stacked in sequence on the solar cell precursor, material of the third transparent conductive layer includes indium tin oxide, material of the second interlayer film is different from the material of the third transparent conductive layer, and material of the fourth transparent conductive layer includes indium tin oxide.

A second aspect of the present application provides a fabrication method for a solar cell. The fabrication method includes: preparing a first transparent conductive layer on a solar cell precursor; preparing a first interlayer film on the first transparent conductive layer; and preparing a second transparent conductive layer on the first interlayer film, where the first transparent conductive layer, the first interlayer film and the second transparent conductive layer are stacked in sequence to form a first transparent conductive film.

In a specific embodiment of the second aspect of the present application, the first transparent conductive layer and the second transparent conductive layer are prepared by a physical vapor deposition process, and the first interlayer film is prepared by a chemical vapor deposition process.

A third aspect of the present application provides a coating device. The coating device includes a first physical vapor deposition chamber, a chemical vapor deposition chamber, and a second physical vapor deposition chamber. The first physical vapor deposition chamber is used to prepare the aforementioned first transparent conductive layer. The chemical vapor deposition chamber is in communication with the first physical vapor deposition chamber. The chemical vapor deposition chamber is used to prepare the aforementioned first interlayer film. The second physical vapor deposition chamber is in communication with the chemical vapor deposition chamber. The second physical vapor deposition chamber is used to prepare the aforementioned second transparent conductive layer.

In a specific embodiment of the third aspect of the present application, the chemical vapor deposition chamber includes a first chemical vapor deposition sub-chamber and a second chemical vapor deposition sub-chamber interconnected with each other, the first chemical vapor deposition sub-chamber is in communication with the first physical vapor deposition chamber, and the second chemical vapor deposition sub-chamber is in communication with the second physical vapor deposition chamber.

In a specific embodiment of the third aspect of the present application, the first physical vapor deposition chamber includes a first physical vapor deposition sub-chamber, a first isolation sub-chamber, and a second physical vapor deposition sub-chamber interconnected with each other, and the first isolation sub-chamber is located between the first physical vapor deposition sub-chamber and the second physical vapor deposition sub-chamber; and/or, the second physical vapor deposition chamber includes a third physical vapor deposition sub-chamber, a second isolation sub-chamber, and a fourth physical vapor deposition sub-chamber interconnected with each other, and the second isolation sub-chamber is located between the third physical vapor deposition sub-chamber and the fourth physical vapor deposition sub-chamber; and/or, the coating device also includes a first connecting chamber, the first connecting chamber is located between the first physical vapor deposition chamber and the chemical vapor deposition chamber, and the first physical vapor deposition chamber and the chemical vapor deposition chamber are in communication with each other via the first connecting chamber; and/or, the coating device also includes a first buffer chamber, the first buffer chamber is located on a side of the first physical vapor deposition chamber away from the chemical vapor deposition chamber, and the first buffer chamber is in communication with the first physical vapor deposition chamber; and/or, the coating device also includes a first vacuum chamber, the first vacuum chamber is located between the chemical vapor deposition chamber and the second physical vapor deposition chamber, and the chemical vapor deposition chamber and the second physical vapor deposition chamber are in communication with each other via the first vacuum chamber.

A fourth aspect of the present application provides a solar cell production system. The solar cell production system includes the coating device according to the aforementioned third aspect.

The present application changes the conventional single-layer transparent conductive film into a multi-layer stacked structure, that is, a first transparent conductive film is configured as a multi-layer stacked structure including a first transparent conductive layer, a first interlayer film, and a second transparent conductive layer. Since material of the first transparent conductive layer includes indium tin oxide, and material of the first interlayer film is different from the material of the first transparent conductive layer, under the condition of the same thickness of the transparent conductive film, the present application may reduce the amount of indium used, thereby effectively reducing the production cost of solar cells and promoting the application and popularization of the solar cells.

### BRIEF DESCRIPTION OF THE DRAWINGS

FIG. 1 is a schematic structural diagram of a solar cell provided by the present application.

FIG. 2 is another schematic structural diagram of a solar cell provided by the present application.

FIG. 3 is a preparation flowchart of a solar cell provided by the present application.

FIG. 4 is another preparation flowchart of a solar cell provided by the present application.

FIG. 5 is a schematic structural diagram of a conventional coating device.

FIG. 6 is a schematic structural diagram of a coating device provided by the present application.

FIG. 7 is a process flowchart for preparing a first transparent conductive film and a second transparent conductive film on a solar cell precursor using the coating device in FIG. 6.

### DETAILED DESCRIPTION OF THE EMBODIMENTS

To facilitate the understanding of the present application, the following will describe the present application more comprehensively with reference to the relevant drawings. The drawings provide preferred embodiments of the present application. However, the present application may be implemented in many different forms and is not limited to the embodiments described herein. Rather, these embodiments are provided to make the disclosure of the present application thorough and complete.

Unless otherwise defined, all technical and scientific terms used herein have the same meanings as commonly understood by those skilled in the technical field to which the present application belongs. The terms used in the specification of the present application are only for the purpose of describing specific embodiments and are not intended to limit the present application. The term “and/or” used herein includes any and all combinations of one or more related listed items.

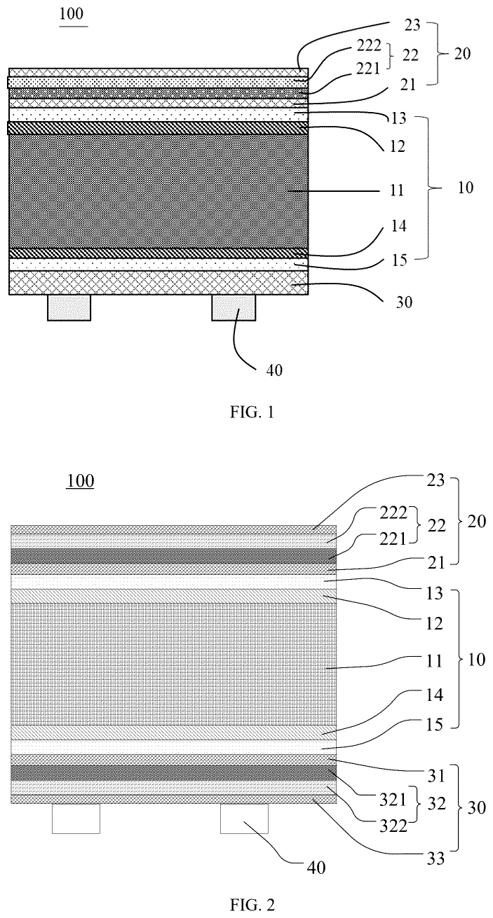

Please refer to FIG. 1. At least one embodiment of the present application provides a solar cell 100. The solar cell 100 includes a solar cell precursor 10, a first transparent conductive film 20, a second transparent conductive film 30 and an electrode 40.

In at least one embodiment, the solar cell precursor 10 includes a silicon wafer 11, a first intrinsic amorphous silicon film 12 and an N-type amorphous silicon film 13 which are stacked in sequence on one surface of the silicon wafer 11, and a second intrinsic amorphous silicon film 14 and a P-type amorphous silicon film 15 which are stacked in sequence on the other surface of the silicon wafer 11. For example, the silicon wafer 11 may be a textured silicon wafer.

In at least one embodiment, the first transparent conductive film 20 is located on the N-type amorphous silicon film 13. For example, the first transparent conductive film 20 includes a first transparent conductive layer 21, a first interlayer film 22, and a second transparent conductive layer 23 which are stacked in sequence on the N-type amorphous silicon film 13.

In at least one embodiment, material of the first transparent conductive layer 21 includes indium tin oxide (ITO). For example, a thickness of the first transparent conductive layer 21 is in a range from 5 nm to 15 nm.

In at least one embodiment, the first interlayer film 22 includes a first interlayer 221 and a second interlayer 222, the first interlayer 221 is located on the first transparent conductive layer 21, the second interlayer 222 is located on the first interlayer 221. For example, materials of the first interlayer 221 and the second interlayer 222 are selected from one of aluminum-doped zinc oxide (AZO) and fluorine-doped tin oxide (FTO), and the material of the first interlayer 221 is different from the material of the second interlayer 222, that is, the material of the first interlayer 221 is selected from one of aluminum-doped zinc oxide and fluorine-doped tin oxide, and the material of the second interlayer 222 is selected from another one of aluminum-doped zinc oxide and fluorine-doped tin oxide. For example, a thickness of the first interlayer 221 is in a range from 38 nm to 39 nm, and a thickness of the second interlayer 222 is in a range from 38 nm to 39 nm.

It should be noted that the first interlayer film 22 of the present application is not limited to only the two-layer structure of the first interlayer 221 and the second interlayer 222. In another embodiment, the first interlayer film 22 may also have a structure of more than two layers, such as three layers, four layers, and so on. That is, the first interlayer film 22 may also include other interlayers in addition to the first interlayer 221 and the second interlayer 222.

In at least one embodiment, material of the second transparent conductive layer 23 includes indium tin oxide. For example, a thickness of the second transparent conductive layer 23 is in a range from 5 nm to 10 nm.

In at least one embodiment, as shown in FIG. 2, the second transparent conductive film 30 is located on the P-type amorphous silicon film 15. For example, the second transparent conductive film 30 includes a third transparent conductive layer 31, a second interlayer film 32, and a fourth transparent conductive layer 33 which are stacked in sequence on the P-type amorphous silicon film 15.

In at least one embodiment, as shown in FIG. 2, material of the third transparent conductive layer 31 includes indium tin oxide (ITO).

In at least one embodiment, as shown in FIG. 2, the second interlayer film 32 includes a third interlayer 321 located on the third transparent conductive layer 33 and a fourth interlayer 322 located on the third interlayer 321. For example, materials of the third interlayer 321 and the fourth interlayer 322 are selected from one of aluminum-doped zinc oxide (AZO) and fluorine-doped tin oxide (FTO), and the material of the third interlayer 321 is different from the material of the fourth interlayer 322, that is, the material of the third interlayer 321 is selected from one of aluminum-doped zinc oxide and fluorine-doped tin oxide, and the material of the fourth interlayer 322 is selected from another one of aluminum-doped zinc oxide and fluorine-doped tin oxide.

It should be noted that the second interlayer film 32 of the present application is not limited to only the two-layer structure of the third interlayer 321 and the fourth interlayer 322. In another embodiment, the second interlayer film may also have a structure of more than two layers, such as three layers, four layers, and so on. That is, the second interlayer film 32 may also include other interlayers in addition to the third interlayer 321 and the fourth interlayer 322.

In at least one embodiment, material of the fourth transparent conductive layer 33 includes indium tin oxide.

In at least one embodiment, the second transparent conductive film 30 may be a single-layer structure, that is, the second transparent conductive film 30 does not have the aforementioned stacked structure but has a single-layer structure. For example, in a case where the second transparent conductive film 30 is a single-layer structure, material of the second transparent conductive film 30 includes indium tin oxide. For example, in a case where the second transparent conductive film 30 is a single-layer structure, a thickness of the second transparent conductive film 30 may be in a range from 100 nm to 120 nm. For example, in a case where the second transparent conductive film 30 is a single-layer structure, the thickness of the second transparent conductive film 30 may be 110 nm.

In one embodiment, the electrode 40 may be located on the first transparent conductive film 20 or may be located on the second transparent conductive film 30. By disposing the electrode 40 on the second transparent conductive film 30, that is, disposing the electrode 40 on a back side of the solar cell 100, compared to conventional solar cells where an electrode is prepared on a front side, the solar cell 100 prepared in the present application may reduce shading of light, thereby improving the light utilization efficiency of the solar cell 100 and enhancing the conversion efficiency of the solar cell 100.

In one embodiment, the electrode 40 may be a metal electrode. For example, the metal electrode may be a copper electrode.

The present application changes the conventional single-layer transparent conductive film into a multi-layer stacked structure, that is, the first transparent conductive film 20 is configured as a multi-layer stacked structure including the first transparent conductive layer 21, the first interlayer film 22, and the second transparent conductive layer 23. Since the material of the first transparent conductive layer 21 includes indium tin oxide, and the material of the first interlayer film 22 is different from the material of the first transparent conductive layer 21, under the condition of the same thickness of the transparent conductive film, the present application may reduce the amount of indium used, thereby effectively reducing the production cost of the solar cell 100 and promoting the application and popularization of the solar cell 100.

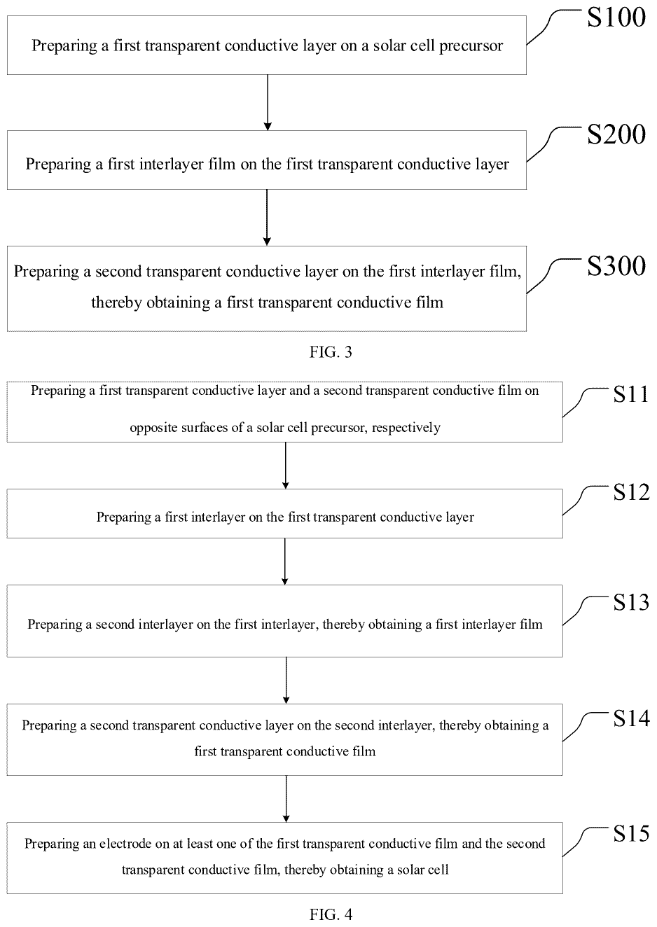

In a process preparation scenario, when preparing the aforementioned first transparent conductive film 20, that is, when preparing the aforementioned first transparent conductive layer 21, the aforementioned first interlayer film 22, and the aforementioned second transparent conductive layer 23, if a physical vapor deposition process is used for all of them, the uniformity and compactness of the prepared first transparent conductive film 20 will be poor, thereby resulting in poor reliability and stability of the prepared solar cell 100. To address the issues of uniformity and density of the first transparent conductive film 20, please refer to FIG. 1 and FIG. 3 simultaneously. The present application also provides a fabrication method for the aforementioned solar cell 100, including the following steps S100 to S300.
Step S100: preparing a first transparent conductive layer on a solar cell precursor.
Step S200: preparing a first interlayer film on the first transparent conductive layer.
Step S300: preparing a second transparent conductive layer on the first interlayer film, the first transparent conductive layer, the first interlayer film and the second transparent conductive layer are stacked in sequence to form a first transparent conductive film.

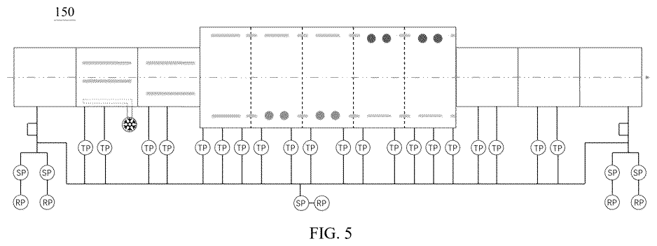

Specifically, as shown in FIG. 4, in one scenario, a preparation process of the aforementioned steps S100 to S300 may be extended as the following steps S11 to S15.
Step S11: preparing a first transparent conductive layer 21 and a second transparent conductive film 30 on opposite surfaces of a solar cell precursor 10, respectively. For specific structures of the solar cell precursor 10, the first transparent conductive layer 21, and the second transparent conductive film 30 may be referred to in the related description in the foregoing embodiments and will not be repeated here.

Specifically, the first transparent conductive layer 21 is prepared on an N-type amorphous silicon film 13 by the physical vapor deposition process, and the second transparent conductive film 30 is prepared on a P-type amorphous silicon film 15 by the physical vapor deposition process.
Step S12: preparing a first interlayer 221 on the first transparent conductive layer 21.

Specifically, the first interlayer 221 is prepared on the first transparent conductive layer 21 by a chemical vapor deposition process. The specific arrangement of the first interlayer 221 may be referred to in the related description in the foregoing embodiments and will not be repeated here.
Step S13: preparing a second interlayer 222 on the first interlayer 221, thereby obtaining a first interlayer film 22.

Specifically, the second interlayer 222 is prepared on the first interlayer 221 by the chemical vapor deposition process, thereby obtaining the first interlayer film 22 including the first interlayer 221 and the second interlayer 222. The specific arrangement of the second interlayer 222 may be referred to in the related description in the foregoing embodiments and will not be repeated here.
Step S14: preparing a second transparent conductive layer 23 on the second interlayer 222, thereby obtaining a first transparent conductive film 20.

Specifically, the second transparent conductive layer 23 is prepared on the second interlayer 222 by the physical vapor deposition process, thereby obtaining the first transparent conductive film 20. The specific arrangement of the second transparent conductive layer 23 may be referred to in the related description in the foregoing embodiments and will not be repeated here.

It can be understood that the first transparent conductive film 20 includes the first transparent conductive layer 21, the first interlayer film 22, and the second transparent conductive layer 23.
Step S15: preparing an electrode 40 on the first transparent conductive film 20 and/or the second transparent conductive film 30 to obtain the solar cell 100.

Preparing the electrode 40 on the second transparent conductive film 30, that is, preparing the electrode 40 on a back side of the solar cell 100, compared to conventional solar cells where an electrode is prepared on a front side, the solar cell 100 prepared in the present application may reduce shading of light, thereby improving the light utilization of the solar cell 100 and enhancing the conversion efficiency of the solar cell 100.

In at least one embodiment, the electrode 40 may be a metal electrode. For example, the metal electrode may be a copper electrode.

Specifically, the electrode 40 may be prepared on the second transparent conductive film 30 by screen printing.

It should be noted that the first interlayer film 22 of the present application is not limited to only the two-layer structure of the first interlayer 221 and the second interlayer 222. For example, the first interlayer film 22 may also have a structure of more than two layers, such as three layers, four layers, and so on, that is, the first interlayer film 22 may also include other interlayers in addition to the first interlayer 221 and the second interlayer 222. For example, other interlayers may be prepared by the chemical vapor deposition process.

The fabrication method provided by the present application prepares the first interlayer 221 on the first transparent conductive layer 21 by the chemical vapor deposition process and prepares the second interlayer 222 on the first interlayer 221 by the chemical vapor deposition process, which may avoid damage to the first interlayer 221 when the second interlayer 222 is prepared using the physical vapor deposition process as previously done, thereby effectively ensuring that an interface between the first interlayer 221 and the second interlayer 222 is undamaged, thus improving the uniformity and compactness of the first transparent conductive film 20, and thereby enhancing the reliability and stability of the prepared solar cell 100.

In at least one embodiment, in a case where the second transparent conductive film 30 is a multi-stack structure, the fabrication method of the second transparent conductive film 30 may be prepared with reference to the fabrication method of the first transparent conductive film 20 described above, which will not be detailed here.

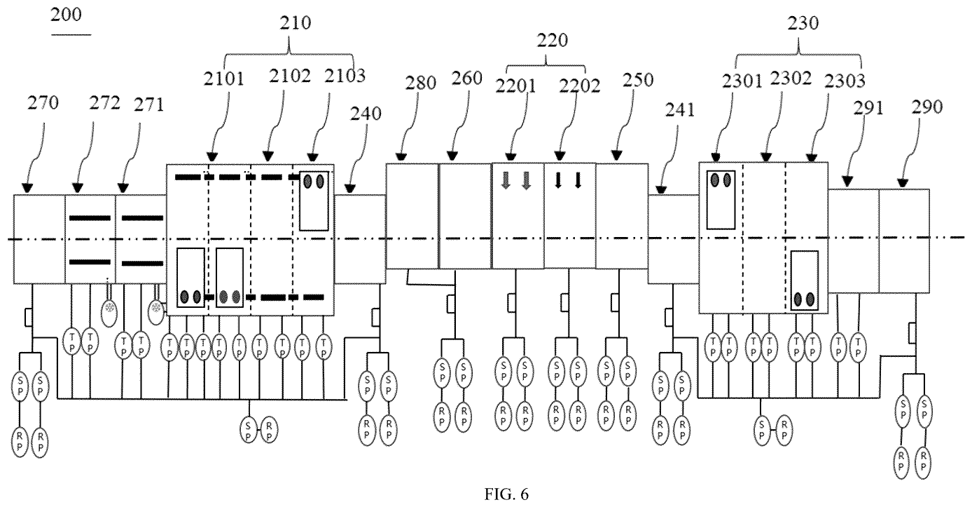

Please refer to FIG. 5, when preparing the aforementioned first transparent conductive film 20, that is, when preparing the aforementioned first transparent conductive layer 21, the first interlayer film 22, and the second transparent conductive layer 23, if the first transparent conductive layer 21 is prepared by the physical vapor deposition process, the first interlayer film 22 is prepared by the chemical vapor deposition process, and the second transparent conductive layer 23 is prepared by the physical vapor deposition process, then three conventional coating devices 150 are required to complete the coating, resulting in poor stability and reliability. To solve the problem of poor stability and reliability in the coating process, please refer to FIG. 1 and FIG. 6 simultaneously. The present application also provides a device for preparing the first transparent conductive film 20 and the second transparent conductive film 30 in the aforementioned solar cell 100, namely a coating device 200.

In at least one embodiment, the coating device 200 includes a first physical vapor deposition chamber 210, a chemical vapor deposition chamber 220, and a second physical vapor deposition chamber 230.

In at least one embodiment, the first physical vapor deposition chamber 210 is in communication with the chemical vapor deposition chamber 220. The first physical vapor deposition chamber 210 is used to prepare the first transparent conductive layer 21 on one surface of the solar cell precursor 10. In actual production, the solar cell precursor 10 is transported into the first physical vapor deposition chamber 210, and the first transparent conductive layer 21 is prepared in the first physical vapor deposition chamber 210 by means such as magnetron sputtering.

In at least one embodiment, the first physical vapor deposition chamber 210 includes a first physical vapor deposition sub-chamber 2101, a first isolation sub-chamber 2102, and a second physical vapor deposition sub-chamber 2103 interconnected with each other, and the first isolation sub-chamber 2102 is located between the first physical vapor deposition sub-chamber 2101 and the second physical vapor deposition sub-chamber 2103. The first physical vapor deposition sub-chamber 2101 is used to prepare a second transparent conductive film intermediate on the other surface of the solar cell precursor 10, and the second physical vapor deposition chamber 230 is used to prepare the first transparent conductive layer 21.

In at least one embodiment, the material of the first transparent conductive layer 21 includes indium tin oxide (ITO). For example, the thickness of the first transparent conductive layer 21 is in a range from 5 nm to 15 nm.

In at least one embodiment, the material of the second transparent conductive film intermediate includes indium tin oxide.

In at least one embodiment, the solar cell precursor 10 includes a silicon wafer 11, a first intrinsic amorphous silicon film 12 and an N-type amorphous silicon film 13 which are stacked in sequence on one surface of the silicon wafer 11, and a second intrinsic amorphous silicon film 14 and a P-type amorphous silicon film 15 which are stacked in sequence on the other surface of the silicon wafer 11. For example, the silicon wafer 11 may be a textured silicon wafer. The first transparent conductive layer 21 is located on the N-type amorphous silicon film 13, and the second transparent conductive film intermediate is located on the P-type amorphous silicon film 15.

In at least one embodiment, the first physical vapor deposition chamber 210 is provided with a first residual gas analysis (RGA) component. The first residual gas analysis component is used to monitor and analyze gases such as water vapor within the first physical vapor deposition chamber 210, thereby enabling better control the preparation effect of the second transparent conductive film intermediate and the first transparent conductive layer 21.

In at least one embodiment, the chemical vapor deposition chamber 220 includes a first chemical vapor deposition sub-chamber 2201 and a second chemical vapor deposition sub-chamber 2202, the second chemical vapor deposition sub-chamber 2202 is in communication with the first chemical vapor deposition sub-chamber 2201. For example, the chemical vapor deposition chamber 220 is used to prepare the first interlayer film 22.

In at least one embodiment, the first chemical vapor deposition sub-chamber 2201 is used to prepare the first interlayer 221 on the first transparent conductive layer 21. For example, the first chemical vapor deposition sub-chamber 2201 is provided with a first sensor and a first wrapping device capable of moving up and down. The first sensor is used to sense the solar cell precursor 10, and the first wrapping device is used to wrap a lower surface of the solar cell precursor 10 to avoid affecting the lower surface of the solar cell precursor 10 when preparing the first interlayer 221, that is, to avoid affecting the second transparent conductive film intermediate. In actual production process, the solar cell precursor 10 with the first transparent conductive layer 21 prepared thereon is transported into the first chemical vapor deposition sub-chamber 2201. At this point, the first sensor will sense the solar cell precursor 10. After the first sensor senses the solar cell precursor 10, the first wrapping device located below inside the first chemical vapor deposition sub-chamber 2201 will automatically rise and wrap the lower surface of the solar cell precursor 10, that is, wrap the second transparent conductive film intermediate. Then, the first interlayer 221 is prepared within the first chemical vapor deposition sub-chamber 2201 by chemical vapor deposition. After the first interlayer 221 is prepared, the first wrapping device will automatically descend to expose the lower surface of the solar cell precursor 10.

In at least one embodiment, material of the first interlayer 221 is selected from one of aluminum-doped zinc oxide (AZO) and fluorine-doped tin oxide (FTO). For example, a thickness of the first interlayer 221 is in a range from 38 nm to 39 nm.

In at least one embodiment, the second chemical vapor deposition sub-chamber 2202 is used to prepare the second interlayer 222 on the first interlayer 221 to obtain the first interlayer film 22. For example, the second chemical vapor deposition sub-chamber 2202 is provided with a second sensor and a second wrapping device capable of moving up and down. The second sensor is used to sense the solar cell precursor 10, and the second wrapping device is used to wrap the lower surface of the solar cell precursor 10 to avoid affecting the lower surface of the solar cell precursor 10 when preparing the second interlayer 222. That is, to avoid affecting the second transparent conductive film intermediate. In the actual production process, the solar cell precursor 10 with the first interlayer 221 prepared thereon is transported into the second chemical vapor deposition sub-chamber 2202. At this time, the second sensor will sense the solar cell precursor 10. After the second sensor senses the solar cell precursor 10, the second wrapping device located below inside the second chemical vapor deposition sub-chamber 2202 will automatically rise and wrap the lower surface of the solar cell precursor 10, that is, wrap the second transparent conductive film intermediate. Then, the second interlayer 222 is prepared within the second chemical vapor deposition sub-chamber 2202 by chemical vapor deposition. After the second interlayer 222 is prepared, the second wrapping device will automatically descend to expose the lower surface of the solar cell precursor 10.

In at least one embodiment, material of the second interlayer 222 is selected from one of aluminum-doped zinc oxide (AZO) and fluorine-doped tin oxide (FTO), and the material of the first interlayer 221 is different from the material of the second interlayer 222. That is, the material of the first interlayer 221 is selected from one of aluminum-doped zinc oxide and fluorine-doped tin oxide, and the material of the second interlayer 222 is selected from another one of aluminum-doped zinc oxide and fluorine-doped tin oxide. For example, a thickness of the second interlayer 222 is in a range from 38 nm to 39 nm.

In at least one embodiment, the chemical vapor deposition chamber 220 is provided with a second residual gas analysis (RGA) component. The second residual gas analysis component is used to monitor and analyze gases such as water vapor within the chemical vapor deposition chamber 220 to better control the preparation effect of the first interlayer 221 and the second interlayer 222.

In at least one embodiment, the second physical vapor deposition chamber 230 is located on a side of the chemical vapor deposition chamber 220 away from the first physical vapor deposition chamber 210, and the second physical vapor deposition chamber 230 is in communication with the chemical vapor deposition chamber 220. In the actual production process, the solar cell precursor 10 with the second interlayer 222 prepared thereon is transported into the second physical vapor deposition chamber 230, and the second transparent conductive layer 23 is prepared within the second physical vapor deposition chamber 230 by means such as magnetron sputtering.

In at least one embodiment, the second physical vapor deposition chamber 230 includes a third physical vapor deposition sub-chamber 2301, a second isolation sub-chamber 2302, and a fourth physical vapor deposition sub-chamber 2303 which are in communication with each other, and the second isolation sub-chamber 2302 is located between the third physical vapor deposition sub-chamber 2301 and the fourth physical vapor deposition sub-chamber 2303. Among them, the third physical vapor deposition sub-chamber 2301 is used to prepare the second transparent conductive layer 23 on the second interlayer 222 to obtain the first transparent conductive film 20, and the fourth physical vapor deposition sub-chamber 2303 is used to perform thickening on the second transparent conductive film intermediate to obtain the second transparent conductive film 30.

In at least one embodiment, material of the second transparent conductive layer 23 includes indium tin oxide. For example, a thickness of the second transparent conductive layer 23 is in a range from 5 nm to 10 nm.

In at least one embodiment, material of the second transparent conductive film 30 includes indium tin oxide. For example, the second transparent conductive film 30 may have a thickness in a range from 100 nm to 120 nm. In a specific embodiment, the second transparent conductive film 30 may have a thickness of 110 nm.

In at least one embodiment, the second physical vapor deposition chamber 230 is provided with a third residual gas analysis (RGA) component. Among them, the third residual gas analysis component is used to monitor and analyze gases such as water vapor within the second physical vapor deposition chamber 230 to better control the preparation effect of the second transparent conductive layer 23 and the second transparent conductive film 30.

In at least one embodiment, the coating device 200 also includes a first connecting chamber 240. For example, the first connecting chamber 240 is located between the second physical vapor deposition sub-chamber 2103 and the first chemical vapor deposition sub-chamber 2201, and the second physical vapor deposition sub-chamber 2103 and the first chemical vapor deposition sub-chamber 2201 are in communication with each other via the first connecting chamber 240. Among them, the first connecting chamber 240 is used to prevent gas leakage from the second physical vapor deposition sub-chamber 2103. In the actual production process, since the first transparent conductive layer 21 is prepared within the second physical vapor deposition sub-chamber 2103 by the physical vapor deposition process, the second physical vapor deposition sub-chamber 2103 contains plasma gas. Providing the first connecting chamber 240 between the second physical vapor deposition sub-chamber 2103 and the first chemical vapor deposition sub-chamber 2201 may prevent the plasma gas in the second physical vapor deposition sub-chamber 2103 from leaking into the first chemical vapor deposition sub-chamber 2201. After the solar cell precursor 10 with the first transparent conductive layer 221 prepared thereon is sent to the first connecting chamber 240, the solar cell precursor 10 will descend from a upper-middle part to a lower-middle part within the first connecting chamber 240, and then enter the first chemical vapor deposition chamber 220 through a vacuum flip valve. After the solar cell precursor 10 descends from the upper-middle part to the lower-middle part within the first connecting chamber 240, a vacant space emerges in the upper-middle part of the first connecting chamber 240. At this time, another solar cell precursor 10 with the first transparent conductive layer 21 prepared thereon will enter the upper-middle part of the first connecting chamber 240, thereby achieving the transition from a continuous-flow physical vapor deposition coating process to a paused chemical vapor deposition coating process. In other words, during the coating process within the first physical vapor deposition chamber 210, the solar cell precursor 10 is in motion, whereas during the coating process within the chemical vapor deposition chamber 220, the solar cell precursor 10 is stationary.

In at least one embodiment, the coating device 200 also includes a second connecting chamber 241. For example, the second connecting chamber 241 is located between the second chemical vapor deposition sub-chamber 2202 and the third physical vapor deposition sub-chamber 2301, and the second chemical vapor deposition sub-chamber 2202 and the third physical vapor deposition sub-chamber 2301 are in communication with each other via the second connecting chamber 241. Among them, the second connecting chamber 241 is used to prevent gas leakage from the third physical vapor deposition sub-chamber 2301. In the actual production process, since the second transparent conductive layer 23 is prepared within the third physical vapor deposition sub-chamber 2301 by the physical vapor deposition process, the third physical vapor deposition sub-chamber 2301 contains plasma gas. Providing the second connecting chamber 241 between the second chemical vapor deposition sub-chamber 2202 and the third physical vapor deposition sub-chamber 2301 may prevent the plasma gas in the third physical vapor deposition sub-chamber 2301 from leaking into the second chemical vapor deposition sub-chamber 2202. Similarly, the solar cell precursor 10 within the second chemical vapor deposition sub-chamber 2202 also enters the third physical vapor deposition sub-chamber 2301 through a vacuum flip valve.

In at least one embodiment, the coating device 200 also includes a first vacuum chamber 250. For example, the first vacuum chamber 250 is located between the second chemical vapor deposition sub-chamber 2202 and the second connecting chamber 241, and the second chemical vapor deposition sub-chamber 2202 and the second connecting chamber 241 are in communication with each other via the first vacuum chamber 250. Among them, the first vacuum chamber 250 is used for providing a vacuum environment for the solar cell precursor 10 on which the preparation of the second interlayer 222 is completed. In the actual production process, the solar cell precursor 10 on which the preparation of the second interlayer 222 is completed is first transported into the first vacuum chamber 250, so that the solar cell precursor 10 is in a vacuum environment. Then, the solar cell precursor 10 in the first vacuum chamber 250 is transported to the second connecting chamber 241.

In at least one embodiment, the coating device 200 also includes a heating chamber 260. For example, the heating chamber 260 is located between the first connecting chamber 240 and the first chemical vapor deposition sub-chamber 2201, and the first connecting chamber 240 and the first chemical vapor deposition sub-chamber 2201 are in communication with each other via the heating chamber 260. Among them, the first heating chamber 260 is used to heat the solar cell precursor 10 on which the preparation of the first transparent conductive layer 21 is completed, to facilitate the preparation of the second transparent conductive film 30 within the first chemical vapor deposition chamber 220.

In at least one embodiment, the coating device 200 also includes a second vacuum chamber 270. For example, the second vacuum chamber 270 is located on a side of the first physical vapor deposition sub-chamber 2101 away from the first connecting chamber 240, and the second vacuum chamber 270 is in communication with the first physical vapor deposition sub-chamber 2101. Among them, the second vacuum chamber 270 is used for providing a vacuum environment for the solar cell precursor 10. In the actual production process, the solar cell precursor 10 may be first placed into the second vacuum chamber 270 by a robotic arm, so that the solar cell precursor 10 is in a vacuum environment. Then, the solar cell precursor 10 in the second vacuum chamber 270 is transported to the first physical vapor deposition sub-chamber 2101 to prepare the second transparent conductive film intermediate.

In at least one embodiment, the coating device 200 also includes a third connecting chamber 271. For example, the third connecting chamber 271 is located between the second vacuum chamber 270 and the first physical vapor deposition sub-chamber 2101, and the second vacuum chamber 270 and the first physical vapor deposition sub-chamber 2101 are in communication with each other via the third connecting chamber 271. Among them, the third connecting chamber 271 is used for preventing gas leakage from the first physical vapor deposition sub-chamber 2101. In the actual production process, since the second transparent conductive film intermediate is prepared within the first physical vapor deposition sub-chamber 2101 by the physical vapor deposition process, the first physical vapor deposition sub-chamber 2101 contains plasma gas. Providing the third connecting chamber 271 between the second vacuum chamber 270 and the first physical vapor deposition sub-chamber 2101 may prevent the plasma gas in the first physical vapor deposition sub-chamber 2101 from leaking into the second vacuum chamber 270.

In at least one embodiment, the coating device 200 also includes a first buffer chamber 272. For example, the first buffer chamber 272 is located between the second vacuum chamber 270 and the third connecting chamber 271, and the second vacuum chamber 270 and the third connecting chamber 271 are in communication with each other via the first buffer chamber 272. Among them, the first buffer chamber 272 is used to perform first buffering processing on the solar cell precursor 10. Thus, during the production process, if an abnormality occurs with the solar cell precursor 10 in the first physical vapor deposition chamber 210, the first buffer chamber 272 may be used to buffer the solar cell precursor 10 that has not yet been unloaded in time, thereby avoiding excessive solar cell precursors 10 from being transported into the first physical vapor deposition chamber 210 and preventing congestion or collisions during transportation that could cause damage, and thus ensuring the production line to operate reliably and stably.

In at least one embodiment, the first buffer chamber 272 may be a device with a storage space.

In at least one embodiment, the coating device 200 also includes a second buffer chamber 280. For example, the second buffer chamber 280 is located between the first connecting chamber 240 and the heating chamber 260, and the first connecting chamber 240 and the heating chamber 260 are in communication with each other via the second buffer chamber 280. Among them, the second buffer chamber 280 is used to perform second buffering processing on the solar cell precursor 10 on which the preparation of the first transparent conductive layer 21 is completed. Thus, during the production process, if an abnormality occurs with the solar cell precursor 10 in the first physical vapor deposition chamber 210, the second buffer chamber 280 may be used to buffer the abnormal solar cell precursor 10, thereby preventing the abnormal solar cell precursor 10 from being transported into the chemical vapor deposition chamber 220. At the same time, the second buffer chamber 280 may also be used to buffer the solar cell precursor 10 that has not yet been unloaded in time, thereby avoiding excessive solar cell precursors 10 from being transported into the chemical vapor deposition chamber 220 and preventing congestion or collisions during transportation that could cause damage, thereby enabling the production line to operate reliably and stably.

In at least one embodiment, the second buffer chamber 280 may be a device with a storage space.

In at least one embodiment, the coating device 200 also includes a second venting chamber 290. For example, the second venting chamber 290 is located on a side of the fourth physical vapor deposition sub-chamber 2303 away from the second connecting chamber 241. Among them, the second venting chamber 290 is in communication with the fourth physical vapor deposition sub-chamber 2303. Among them, the second venting chamber 290 is used to provide an atmospheric pressure environment for the solar cell precursor 10 on which the preparation of the first transparent conductive film 20 and the second transparent conductive film 30 are completed.

In at least one embodiment, the solar cell precursor 10 on which the preparation of the first transparent conductive film 20 and the second transparent conductive film 30 are completed may be removed from the second venting chamber 290 by a robotic arm.

In at least one embodiment, the coating device 200 also includes a fourth connecting chamber 291. For example, the fourth connecting chamber 291 is located between the fourth physical vapor deposition sub-chamber 2303 and the second venting chamber 290, and the fourth physical vapor deposition sub-chamber 2303 and the second venting chamber 290 are in communication with each other via the fourth connecting chamber 291. Among them, the fourth connecting chamber 291 is used to prevent gas leakage from the fourth physical vapor deposition sub-chamber 2303. In the actual production process, since the thickening of the second transparent conductive film intermediate is performed within the fourth physical vapor deposition sub-chamber 2303 by the physical vapor deposition process, the fourth physical vapor deposition sub-chamber 2303 contains plasma gas. Providing the fourth connecting chamber 291 between the fourth physical vapor deposition sub-chamber 2303 and the second venting chamber 290 may prevent the plasma gas in the fourth physical vapor deposition sub-chamber 2303 from leaking into the second venting chamber 290.

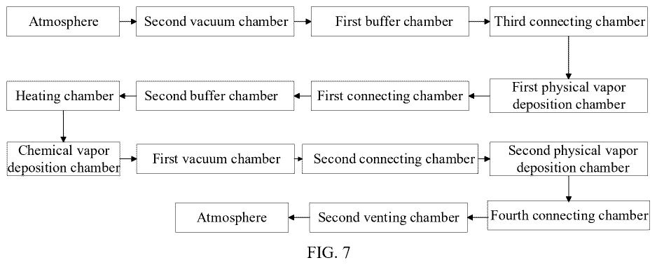

As shown in FIG. 6 and FIG. 7, the solar cell precursor 10 is placed from the atmosphere into the second vacuum chamber 270 by a robotic arm, and then the solar cell precursor 10 in the second vacuum chamber 270 is transported sequentially through the first buffer chamber 272 and the third connecting chamber 271 to the first physical vapor deposition sub-chamber 2101. The first physical vapor deposition sub-chamber 2101 prepares the second transparent conductive film intermediate on the P-type amorphous silicon film 15 of the solar cell precursor 10. After passing through the first isolation sub-chamber 2102, the second physical vapor deposition sub-chamber 2103 prepares the first transparent conductive layer 21 on the N-type amorphous silicon film 13 of the solar cell precursor 10. Then, the solar cell precursor 10 with the first transparent conductive layer 21 prepared thereon is transported sequentially through the first connecting chamber 240, the second buffer chamber 280, and the heating chamber 260 to the first chemical vapor deposition sub-chamber 2201. The first chemical vapor deposition sub-chamber 2201 prepares the first interlayer 221 on the first transparent conductive layer 21. The solar cell precursor 10 with the first interlayer 221 prepared thereon is transported to the second chemical vapor deposition sub-chamber 2202. The second chemical sub-chamber prepares the second interlayer 222 on the first interlayer 221. Then, the solar cell precursor 10 with the second interlayer 222 prepared thereon is transported sequentially through the first vacuum chamber 250 and the second connecting chamber 241 to the third physical vapor deposition sub-chamber 2301. The third physical vapor deposition sub-chamber 2301 prepares the second transparent conductive layer 23 on the second interlayer 222, thereby obtaining the first transparent conductive film 20. After passing through the second isolation sub-chamber 2302, the fourth physical vapor deposition sub-chamber 2303 thickens the second transparent conductive film intermediate, thereby obtaining the second transparent conductive film 30 and finally obtaining the finished product. The finished product is transported through the fourth connecting chamber 291 to the second venting chamber 290. Another robotic arm removes the finished product from the second venting chamber 290 and places the finished product in the atmosphere.

At least one embodiment of the present application provides a solar cell 100 production system. The solar cell 100 production system includes the aforementioned coating device 200.

The coating device 200 provided by the present application includes the first physical vapor deposition chamber 210, the chemical vapor deposition chamber 220, and the second physical vapor deposition chamber 230. The present application may prepare the first transparent conductive film 20 with a stacked structure using only one coating device 200, without requiring three coating apparatuses, thereby improving the stability and reliability of the coating process. It can be understood that in a case where the second transparent conductive film 30 has a multi-stacked structure, it may also be prepared using the aforementioned coating device 200.

In addition, the coating device 200 provided by the present application has the following advantages:
First, an original physical vapor deposition chamber is modified into a hybrid vapor deposition chamber, which not only retains the functions of the original physical vapor deposition chamber but also achieves a goal of using one coating device 200 to prepare a first transparent conductive film 20 with a multi-stacked structure.
Second, it has no impact on manufacturing process and reduces the workload of employees.
Third, the original one-step formation process of the transparent conductive film has been split into a two-step formation process, thereby improving the uniformity and compactness of the first transparent conductive film 20 and the second transparent conductive film 30.
Fourth, it reduces manual intervention, eliminating the need for frequent manual debugging of process recipe, thereby improving the stability of the production line.
Fifth, the processes in the first physical vapor deposition chamber 210, the chemical vapor deposition chamber 220, and the second physical vapor deposition chamber 230 do not interfere with each other and are carried out simultaneously, which has a significant positive impact on enhancing production capacity.

The technical features of the above embodiments may be arbitrarily combined. To keep the description concise, not all possible combinations of the technical features in the above embodiments are described. However, as long as there is no contradiction in the combination of these technical features, all such combinations should be considered as falling within the scope of this specification.

The above embodiments only express several implementation methods of the present application, and their descriptions are relatively specific and detailed, but they should not be construed as limiting the scope of the patent. It should be noted that for those skilled in the art, without departing from the concept of the present application, several modifications and improvements may be made, all of which fall within the protection scope of the present application. Therefore, the protection scope of the patent application shall be subject to the appended claims. What is claimed is:

1. A coating device for preparing a solar cell, comprising:
a first physical vapor deposition chamber used to prepare a first transparent conductive layer on a solar cell precursor of the solar cell;
a chemical vapor deposition chamber in communication with the first physical vapor deposition chamber, wherein the chemical vapor deposition chamber is used to prepare a first interlayer film on the first transparent conductive layer; and
a second physical vapor deposition chamber in communication with the chemical vapor deposition chamber, the second physical vapor deposition chamber being used to prepare a second transparent conductive layer on the first interlayer film, wherein the first transparent conductive layer, the first interlayer film and the second transparent conductive layer are stacked in sequence to form a first transparent conductive film.

2. The coating device according to claim 1, wherein the chemical vapor deposition chamber comprises a first chemical vapor deposition sub-chamber and a second chemical vapor deposition sub-chamber interconnected with each other, the first chemical vapor deposition sub-chamber is in communication with the first physical vapor deposition chamber, and the second chemical vapor deposition sub-chamber is in communication with the second physical vapor deposition chamber.

3. The coating device according to claim 2, wherein the first physical vapor deposition chamber comprises a first physical vapor deposition sub-chamber, a first isolation sub-chamber, and a second physical vapor deposition sub-chamber interconnected with each other, and the first isolation sub-chamber is located between the first physical vapor deposition sub-chamber and the second physical vapor deposition sub-chamber.

4. The coating device according to claim 3, wherein the second physical vapor deposition chamber comprises a third physical vapor deposition sub-chamber, a second isolation sub-chamber, and a fourth physical vapor deposition sub-chamber interconnected with each other, and the second isolation sub-chamber is located between the third physical vapor deposition sub-chamber and the fourth physical vapor deposition sub-chamber.

5. The coating device according to claim 3, further comprising a first connecting chamber, wherein the first connecting chamber is located between the first physical vapor deposition chamber and the chemical vapor deposition chamber, and the first physical vapor deposition chamber and the chemical vapor deposition chamber are in communication with each other via the first connecting chamber.

6. The coating device according to claim 3, further comprising a first buffer chamber, wherein the first buffer chamber is located on a side, away from the chemical vapor deposition chamber, of the first physical vapor deposition chamber, and the first buffer chamber is in communication with the first physical vapor deposition chamber.

7. The coating device according to claim 3, further comprising a first vacuum chamber, wherein the first vacuum chamber is located between the chemical vapor deposition chamber and the second physical vapor deposition chamber, and the chemical vapor deposition chamber and the second physical vapor deposition chamber are in communication with each other via the first vacuum chamber.

8. The coating device according to claim 1, wherein the first physical vapor deposition chamber comprises a first physical vapor deposition sub-chamber, a first isolation sub-chamber, and a second physical vapor deposition sub-chamber interconnected with each other, and the first isolation sub-chamber is located between the first physical vapor deposition sub-chamber and the second physical vapor deposition sub-chamber.

9. The coating device according to claim 1, wherein the second physical vapor deposition chamber comprises a third physical vapor deposition sub-chamber, a second isolation sub-chamber, and a fourth physical vapor deposition sub-chamber interconnected with each other, and the second isolation sub-chamber is located between the third physical vapor deposition sub-chamber and the fourth physical vapor deposition sub-chamber.

10. The coating device according to claim 1, further comprising a first connecting chamber, wherein the first connecting chamber is located between the first physical vapor deposition chamber and the chemical vapor deposition chamber, and the first physical vapor deposition chamber and the chemical vapor deposition chamber are in communication with each other via the first connecting chamber.

11. The coating device according to claim 1, further comprising a first buffer chamber, wherein the first buffer chamber is located on a side, away from the chemical vapor deposition chamber, of the first physical vapor deposition chamber, and the first buffer chamber is in communication with the first physical vapor deposition chamber.

12. The coating device according to claim 1, further comprising a first vacuum chamber, wherein the first vacuum chamber is located between the chemical vapor deposition chamber and the second physical vapor deposition chamber, and the chemical vapor deposition chamber and the second physical vapor deposition chamber are in communication with each other via the first vacuum chamber.

13. A solar cell prepared based on the coating device according to claim 1, comprising:
a solar cell precursor; and
a first transparent conductive film, located on the solar cell precursor;
wherein the first transparent conductive film comprises a first transparent conductive layer, a first interlayer film, and a second transparent conductive layer which are stacked in sequence on the solar cell precursor, and
material of the first transparent conductive layer comprises indium tin oxide, material of the first interlayer film is different from the material of the first transparent conductive layer, and material of the second transparent conductive layer comprises indium tin oxide.

14. The solar cell according to claim 13, wherein the first interlayer film has a structure comprising at least two layers.

15. The solar cell according to claim 14, further comprising:
a second transparent conductive film, wherein the second transparent conductive film and the first transparent conductive film are respectively located on opposite surfaces of the solar cell precursor;
wherein the second transparent conductive film comprises a third transparent conductive layer, a second interlayer film, and a fourth transparent conductive layer which are stacked in sequence on the solar cell precursor, material of the third transparent conductive layer comprises indium tin oxide, material of the second interlayer film is different from the material of the third transparent conductive layer, and material of the fourth transparent conductive layer comprises indium tin oxide.

16. The solar cell according to claim 13, wherein the first interlayer film comprises a first interlayer and a second interlayer, the first interlayer is located on the first transparent conductive layer, the second interlayer is located on the first interlayer, materials of the first interlayer and the second interlayer are selected from one of aluminum-doped zinc oxide and fluorine-doped tin oxide, and the material of the first interlayer is different from the material of the second interlayer.

17. The solar cell according to claim 16, further comprising:
a second transparent conductive film, wherein the second transparent conductive film and the first transparent conductive film are respectively located on opposite surfaces of the solar cell precursor;
wherein the second transparent conductive film comprises a third transparent conductive layer, a second interlayer film, and a fourth transparent conductive layer which are stacked in sequence on the solar cell precursor, material of the third transparent conductive layer comprises indium tin oxide, material of the second interlayer film is different from the material of the third transparent conductive layer, and material of the fourth transparent conductive layer comprises indium tin oxide.

18. The solar cell according to claim 13, further comprising:
a second transparent conductive film, wherein the second transparent conductive film and the first transparent conductive film are respectively located on opposite surfaces of the solar cell precursor;
wherein the second transparent conductive film comprises a third transparent conductive layer, a second interlayer film, and a fourth transparent conductive layer which are stacked in sequence on the solar cell precursor, material of the third transparent conductive layer comprises indium tin oxide, material of the second interlayer film is different from the material of the third transparent conductive layer, and material of the fourth transparent conductive layer comprises indium tin oxide.

19. A solar cell production system, comprising the coating device according to claim 1.
